(19) United States
(12) Patent Application Publication
(10) Pub. No.: US 2017/0307669 A1
(43) Pub. Date: Oct. 26, 2017

(54) DEVICE AND METHOD FOR TESTING A MIXER

(71) Applicant: Infineon Technologies AG, Neubiberg (DE)

(72) Inventors: Johann Peter Forstner, Steinhoering (DE); Ismail Nasr, Unterhaching (DE); Vadim Issakov, Muenchen (DE); Saverio Trotta, Muenchen (DE); Markus Ortner, Linz (AT)

(73) Assignee: Infineon Technologies AG, Neubiberg (DE)

(21) Appl. No.: 15/133,878

(22) Filed: Apr. 20, 2016

(51) Int. Cl. G01R 27/28; H04B 17/29

(52) U.S. Cl. CPC G01R 27/28; H04B 17/29

(57) ABSTRACT

A device and method for testing a mixer. For testing, signals having essentially the same frequency are applied to local oscillator (LO) and radio frequency (RF) inputs of the mixer. The signals phase-shifted with respect to each other and an output of the mixer is measured to provide a result.

### TECHNICAL FIELD

The present application relates to devices and methods, and more particularly to devices and methods for testing a mixer.

### BACKGROUND

With the increased demand for millimeter wave-based radio frequency (RF) systems, there has been a corresponding interest in integrating such RF systems on silicon-based integrated circuits instead of using discrete III/V-based semiconductor components. Millimeter wave frequencies as used herein may refer to frequencies between about 30 GHz and about 300 GHz. Common applications for millimeter wave-based RF systems include, for example, automotive radar and high frequency communication systems. By using silicon integration, large volumes of these RF systems can be manufactured at lower costs than discrete component-based systems.

Testing millimeter wave-based systems, however, may be difficult and comparatively expensive. For example, in systems that operate at over 10 GHz, precision test fixtures and equipment conventionally used to test these systems are expensive. These test fixtures and equipment are comparatively time consuming to operate, calibrate and maintain, and RF probes used for testing have a limited lifetime and wear out over time. Physical deformations, such as bent contacts, can affect high frequency matching networks and corrosion of contacts and connectors can degrade attenuation characteristics of such a test setup. Furthermore, the expertise required to maintain and operate such RF equipment is not often available in high volume semiconductor test environments. As such, even if large volumes of millimeter wave RF integrated circuits can be manufactured, the testing of the integrated circuits may result in a bottleneck that reduces throughput.

One type of circuit component frequently employed in such RF systems, but also in other systems, is a mixer. Mixers generally mix a signal having a first frequency with a signal having a second frequency, resulting in a signal having a third frequency. For example, such mixers are used in frequency downconverters such as homodyne millimeter wave frequency downconverters. For such downconverters, for example, an incoming RF signal is mixed with a local oscillator (LO) signal resulting in an intermediate frequency (IF) signal which may then be further processed. For testing such mixers or other RF circuits, conventional and comparatively expensive RF test equipment has to be placed and operated within a production environment, which is not desirable. Furthermore, high frequency test signals have to be provided to the device under test and also measured at the device under test. For mass fabrication, the precision of this test approach may be limited, and the costs are high.

An alternative approach to the above-described test equipment which has been developed recently is to generate the necessary signals for performing a test on the chip itself. This approach may be used for built-in self-test (BIST) without the use of any external testing equipment if corresponding evaluation circuitry for evaluating the test measurements are also included on the chip. With current testing approaches, for example, a LO signal is generated by a digitally controlled VCO (voltage controlled oscillator), and a test signal for an RF input of the mixer is generated using a single side band modulator. For operation of these single side band modulators, two external IF input signals with a relative phase shift of 90° are required. For supplying these signals, an additional analog test interface is required with additional package pins. Furthermore, while this approach works generally well and is an improvement over previous approaches that use test equipment, the additional components required on the chip will require considerable chip area.

### SUMMARY

According to an embodiment of a radio frequency (RF) device, the device includes a mixer and a test circuit. The mixer includes a RF input, a local oscillator (LO) input and an output. The test circuit includes a phase shifter and is configured to apply, in a test mode, a first input signal to the LO input and a second input signal to the RF input. The first input signal and the second input signal have essentially a same frequency. The phase shifter is configured to phase-shift the first input signal relative to the second input signal.

According to an embodiment of a method, the method includes providing a first test signal and a second test signal, where the first test signal and the second test signal have essentially a same frequency. The method includes setting one or more phase differences between the first test signal and the second test signal and applying, for each one of the one or more phase differences, the first test signal to a LO input of a mixer and the second test signal to a RF input of the mixer. The method includes measuring an output of the mixer for each one of the one or more phase differences to provide a corresponding one or more measurement results, and evaluating the one or more measurement results to determine one or more values for the mixer.

According to an embodiment of a RF device, the device includes a LO terminal, a RF signal terminal, and a mixer that includes a LO input, a RF input and an intermediate frequency (IF) output. The LO input is coupled to the LO terminal via a first coupler and the RF input is coupled to the RF terminal via a second coupler. The device includes a buffer configured to couple the first coupler to the second coupler during a test mode, a controllable phase shifter configured to phase-shift a LO input signal relative to a RF input signal during the test mode and a power detector configured to detect a power of the RF input signal.

The above summary is merely intended to provide a brief overview of some embodiments and features and is not to be construed as limiting. In particular, other embodiments may include different features than the ones set forth above.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a schematic block diagram of a device according to an embodiment.

FIG. 2 is a block diagram illustrating a device according to an embodiment.

FIGS. 3A-3C are diagrams for illustrating operation of a device in some embodiments.

FIG. 4 is a flowchart illustrating a method according to an embodiment.

FIG. 5 is a block diagram illustrating a device according to an embodiment.

FIG. 6 is a diagram illustrating a device according to an embodiment.

### DETAILED DESCRIPTION

In the following, various embodiments will be discussed in reference to the attached drawings. While embodiments may be described using particular details, features or elements, this is for illustration purposes only and is not to be construed as limiting. For example, in other embodiments some of the details, features or elements may be omitted and/or be replaced by alternative details, features or elements. Furthermore, in embodiments apart from the features or elements explicitly discussed and shown in the drawings, other features or elements, for example features or elements conventionally used in mixer testing and/or in RF circuits, may be provided.

Features or elements from different embodiments may be combined to form further embodiments. Variations or modifications described with respect to one of the embodiments may also be applicable to other elements. Any electrical connections or couplings between elements shown may be direct connections or couplings, i.e. connections or coupling without additional intervening elements, for example may be simple metal connections, or may be indirect connections or couplings, i.e. connections or couplings including one or more additional intervening elements, as long as the general purpose of the connection or coupling, for example to transmit a certain kind of signal or information or to provide a certain kind of control, is essentially maintained. Any numerical values or signal waveforms given are merely for illustration purposes, and numerical values or signal waveforms may vary according to a particular implementation.

In various embodiments, a first test signal applied to a radio frequency (RF) input of a mixer and a second test signal applied to a local oscillator (LO) input of the mixer have essentially the same frequency, for example, are derived from or based on the same signal. In embodiments, the first and second test signals are applied with varying phase differences, and based on a response of the mixer a property of the mixer may be determined, or correct operation of the mixer may be ascertained. Examples for such concepts and techniques will now be discussed referring to the Figures by way of example.

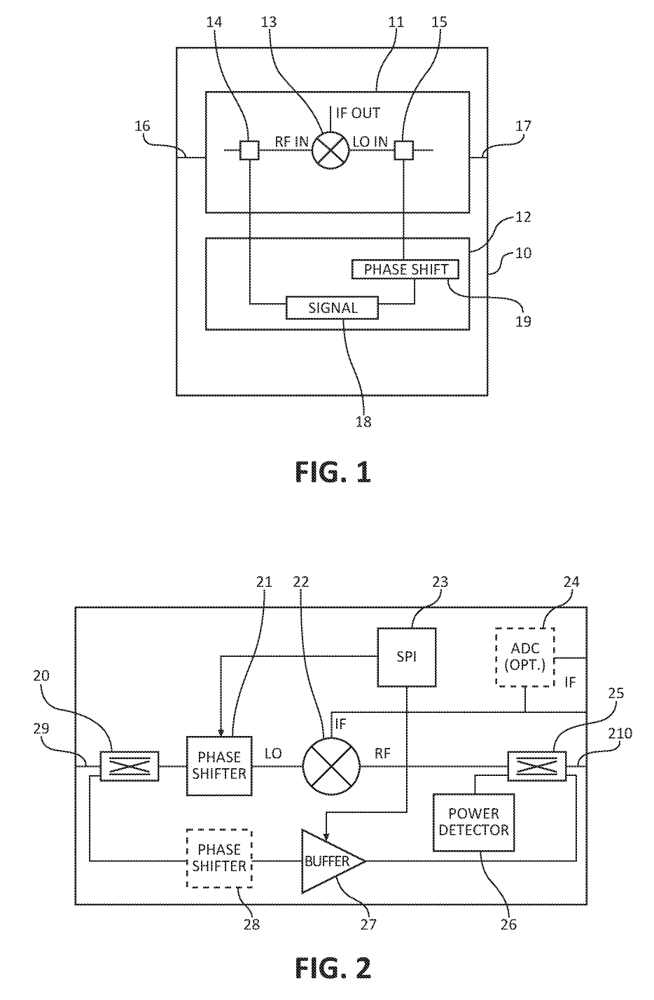

Turning now to the Figures, in FIG. 1 a RF device 10 according to an embodiment is schematically shown. Device 10 may for example be implemented on a single chip die, or alternatively may also be implemented on a plurality of chip dies. Such a plurality of chip dies may be provided in a common package, or also in separate packages. Device 10 includes an RF circuit portion 11 and a test circuit portion 12. While for the sake of illustration RF circuit portion 11 and test circuit portion 12 are depicted as separate blocks, the corresponding components may be integrated in a single circuit.

RF circuit portion 11 includes a mixer 13. Mixer 13 receives an RF signal RFin at an RF input and a local oscillator signal LOin at an LO input and outputs an intermediate frequency (IF) signal IFout at an IF output. In various embodiments, any suitable implementation may be used for mixer 13.

The RF signal RFin may for example be or be derived from an RF signal received via an input terminal 16, and the RF circuit portion 11 may output a signal based on IFout via an output terminal 17. It should be noted that as the following explanations will focus on how to test mixer 13, only mixer 13 is illustrated in RF circuit portion 11 of FIG. 1. However, RF circuit portion 11 in addition to mixer 13 may comprise any suitable components employed in RF circuits, like filters, mixers, buffers, amplifiers, etc. Furthermore, while a single mixer 13 is illustrated in FIG. 1, in other embodiments more than one mixer may be used, and one or more of such mixers may be tested using techniques as illustrated below.

To test mixer 13, a signal schematically labelled 18 in FIG. 1 is provided to the RF input of mixer 13 via a coupler 14 and to the LO input of mixer 13 via a coupler 15. The versions of signal 18 applied to the above mentioned two inputs of mixer 13 are phase-shifted with respect to each other, as indicated by a phase shifter 19. Phase shifter 19 may be implemented in any suitable manner and may apply a configurable phase shift. In particular, as will be explained later in more detail, for testing mixer 13 the phase shift may be varied. While in the schematic representation of FIG. 1 phase shifter 19 is provided between signal 18 and coupler 15, phase shifter 19 may also be provided between signal 18 and coupler 14 or at any other position ensuring a relative phase shift between the two signals applied to the inputs of mixer 13. In other embodiments, more than one phase shifter may be used for generating the phase shift.

Signal 18 may be generated by a signal source such as a voltage controlled oscillator and may have a frequency similar to the frequency of the LO signal LOin. In some embodiments, a local oscillator that is used for generating LOin in normal operation may also be used for generating the signal 18. In other embodiments, the signal 18 may be applied via an external signal input, for example via input terminal 16. Therefore, various configurations are possible as long as two signals having the same or essentially the same (for example ±5% or ±10%) frequency to two inputs of mixer 13 with an adjustable phase shift.

FIG. 2 illustrates a block diagram of a device according to an embodiment, where the above concepts illustrated with respect to FIG. 1 will be discussed in greater detail.

The embodiment of FIG. 2 includes a mixer 22 that is to be tested. Mixer 22 may for example be a homodyne mixer of an RF receiver or part thereof. In normal operation, mixer 22 receives a local oscillator signal LO via a terminal 29 and an RF signal via a terminal 210 as input signals and outputs an intermediate frequency signal IF. Any number of suitable approaches may be used to perform the mixing function of mixer 22.

Furthermore, the circuit of FIG. 2 comprises couplers 20, 25. In normal operation (without testing), coupler 20 simply forwards the LO signal received at terminal 29 to an LO input of mixer 22, and coupler 25 forwards the RF signal received at terminal 210 to an RF input of mixer 22. Couplers 20, 25 may be realized based on a variety of coupling effects, and any suitable coupler may be used. These include, but are not limited to, directional couplers or attenuation pads or couplers based on capacitive and/or inductive coupling.

For testing purposes, the circuit of FIG. 2 furthermore comprises a phase shifter 21, a power detector 26 and a buffer 27. Phase shifter 21 and buffer 27 are controlled via a serial peripheral interface (SPI) 23, via which the circuit may be switched between a regular mode of operation and a test mode. Instead of control by SPI 23, in other embodiments, other suitable types or methods of control may be used. These include, but are not limited to, other types of interfaces or control via an internal controller.

In test mode, a LO signal generated by a local oscillator continues to be supplied at terminal 29. Furthermore, in test mode, buffer 27 is controlled via SPI 23 to be active such that the LO signal is forwarded via coupler 25 to the RF input of mixer 22. It should be noted that in regular operation (outside of test mode), buffer 27 is deactivated, thus effectively interrupting the path from coupler 20 to coupler 25 via buffer 27. Phase shifter 21 is controlled to provide varying phase shifts. In the position of phase shifter 21 shown in FIG. 2, the signal provided to the LO input of mixer 22 is phase-shifted. Alternatively, instead of phase shifter 21 a phase shifter may also be provided in the path from coupler 20 to coupler 25 via buffer 27, for example as phase shifter 28 indicated in FIG. 2, such that the signal applied to the RF input of mixer 22 is phase-shifted. In other embodiments, a phase shifter may be provided both at the position shown for phase shifter 21 in FIG. 2 and the path from coupler 20 to coupler 25 via buffer 27, e.g. as indicated by phase shifter 28. In all cases, an adjustable relative phase shift between the signals provided to the LO and RF inputs of mixer 22 may be provided.

Phase shifter 21 may be implemented in a variety of ways. In various embodiments, a passive phase shifter that includes, for example, switchable delay lines and/or varactor tuned delays may be used. In other embodiments, active phase shifters, for example vector modulators or phase shifters using a synthesis by superpositioning of sine waves may be used. In other embodiments, other suitable types of phase shifters may be used.

Buffer 27 as described in the illustrated embodiments provides an on/off functionality to selectively couple coupler 20 to coupler 25 via buffer 27. In some embodiments, instead of a buffer, a simple switch may be used which may be opened or closed.

In addition, the device of FIG. 2 comprises a power detector 26 coupled to coupler 25 to detect a power of the signal supplied to the RF input of mixer 22. In various embodiments, power detector 26 may use any suitable active or passive detection approach to detect the power of the signal supplied to the RF input of mixer 22. Power detector 26 may include circuitry to compensate for environmental changes, for example, temperature or supply voltage changes. In the illustrated embodiment, a power value measured by power detector 26 may be read out as an analog signal, for example via an analog multiplexer, or in digital form, using for example a digital interface after an analog to digital conversion.

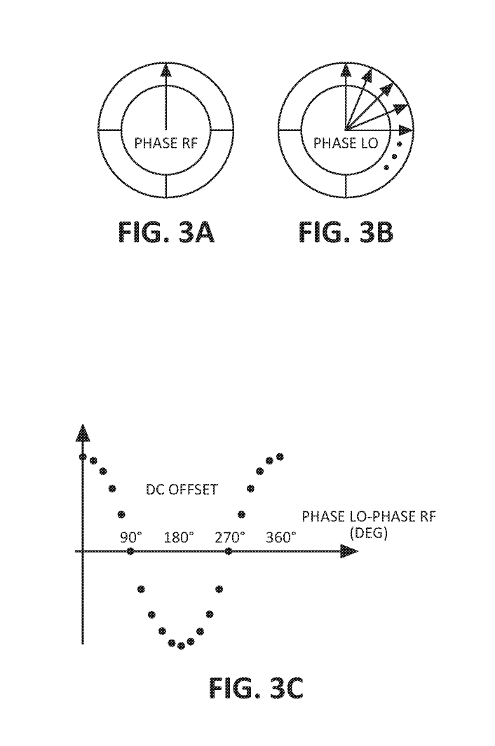

The IF signal generated by mixer 22 may be output in analog form or in digital form via an optional analog to digital converter 24. For testing mixer 22 and/or for determining properties thereof, the IF signal is evaluated for example for different phase shifts applied by phase shifter 21. This will be now explained with reference to FIGS. 3A-3C.

Generally, mixer 22 for signals at its local oscillator LO and radio frequency RF inputs having the same frequency outputs a DC signal (i.e. a signal with frequency zero). As apart from phase-shifting with the testing scheme of FIG. 2, the same signal is applied to the LO and RF inputs, the frequencies are essentially the same, albeit slight changes due to parasitic effects could occur in some implementations. The magnitude of the DC output depends on the phase shift between the signals. Furthermore, the DC offset depends on the power of the signal applied to the RF input of mixer 22. In contrast, in most mixer implementations the power is essentially independent from the power of the signal applied to the LO input. This will now be further explained in reference to FIGS. 3A-3C.

FIGS. 3A and 3B illustrate phase diagrams illustrating a phase of a signal provided to the RF input of mixer 22 (FIG. 3A), and varying phases of a signal provided to the LO input of mixer 22 (FIG. 3B). The example of FIGS. 3A and 3B corresponds to the position of phase shifter 21 in FIG. 2 varying the phase of the signal fed to the LO input. If the phase shifter 21 were positioned as indicated by arrow 28, the phase of the LO signal would be fixed and a phase of the RF signal would vary. In the embodiment illustrated in FIG. 3B, the phase varies in steps of 22.5 degrees. In other embodiments, other suitable variations are possible.

FIG. 3C illustrates a DC offset signal IF output by mixer 22 for different phase offsets between the signal at the LO terminal and the signal at the RF terminal during testing, i.e. when both signals have essentially the same frequency. As can be seen, the DC offset behaves according to a cosine function over the phase shift. The peak-to-peak value of this cosine function depends on the power of the RF signal, which is measured by the power detector. A ratio of the peak-to-peak value of the DC offset to the input power of the signal at the RF terminal essentially corresponds to or is proportional to the mixer conversion gain. Therefore, the mixer may be tested, and its conversion gain may be measured with the test circuit as illustrated above. In other embodiments, as will be explained later, additional components may be coupled to the mixer, and the testing may test the circuit that includes the mixer and the additional components.

With the embodiment of FIG. 2, no analog IF test interface supplying IF signals and no corresponding package pins are required to perform the tests. The test may be controlled via an SPI or other suitable interface. The testing may be implemented as a built-in-self-test which may also be performed for example, in regular intervals or regular intervals during use, or may be implemented as a post-production test which can be permanently deactivated (by setting buffer 27 to an inactive state, for example) before shipping the device to a customer.

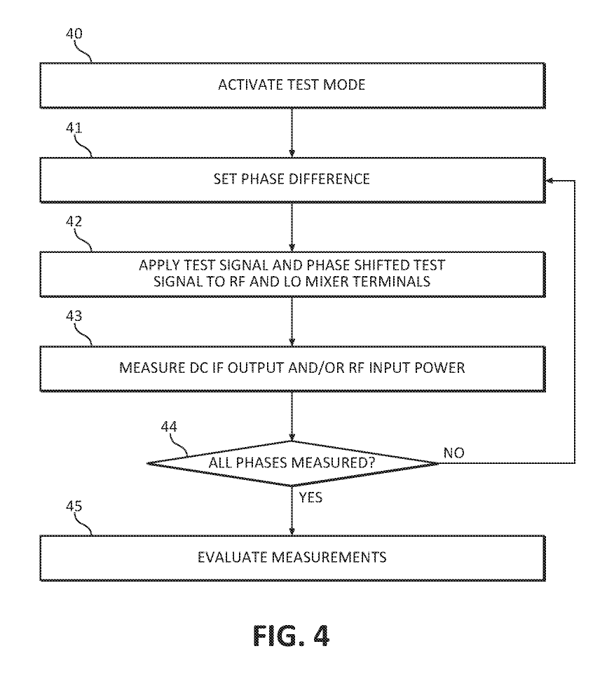

To illustrate testing further, FIG. 4 is a flowchart illustrating a method according to an embodiment. In various embodiments, the method of FIG. 4 may be implemented in the devices illustrated with respect to FIGS. 1 and 2 and for better understanding will be described in reference to these devices as examples. However, application of the method of FIG. 4 is not limited to the devices shown in FIGS. 1 and 2. The method may be controlled in devices via an interface like a serial peripheral interface (like SPI 23 of FIG. 2) or may for example also be controlled by an on-chip controller, for example, a microcontroller or any other suitable controller. While the method is described as a series of acts or events, the order in which the acts or events are described is not to be construed as limiting.

At 40 in FIG. 4, the method includes activating a test mode. For example, in the device of FIG. 2 activating the test mode may comprise setting buffer 27 to an active state such that the local oscillator signal is forwarded to coupler 25.

At 41, the method includes setting a phase difference, for example by controlling phase shifter 19 of FIG. 1 or controlling phase shifter 21 of FIG. 2. At 42, the method comprises applying a test signal and a phase-shifted (by the phase difference set at 41) test signal to RF and LO terminals of a mixer. As explained previously, the phase shifting may be performed with the signal applied to the RF terminal, the LO terminal or to both the RF terminal and the LO terminal, to provide a desired phase difference between the signals. At 43, the method comprises measuring the DC IF output of the mixer, for example in analog form or via an analog-to-digital converter like analog-to-digital converter 24. In other embodiments, the method at 43 includes measuring a power of the signal applied to the RF terminal of the mixer.

At 44, if all desired phases are not measured, the method reverts to 41 to set a different phase difference, for example by incrementing the phase difference by a predetermined value (e.g. 22.5° or 45°). When all the phases are measured (for example over) 360°, at 45 the method comprises evaluating the measurements. For example, a sine function or cosine function may be fitted to the measurements, and the peak-to-peak DC offset value may be determined based on the fit. In other embodiments, other algorithms or approaches may be used to find peak values in the measurement and to determine a peak-to-peak offset. In other embodiments, only half of a period may be measured, and a peak-to-zero ratio may be determined. In some embodiments, measuring at least one full period (from 0 to 360°) may increase accuracy. In the illustrated embodiment, based on the DC offset and the power of the RF signal, as explained above, a conversion gain of the mixer may be determined.

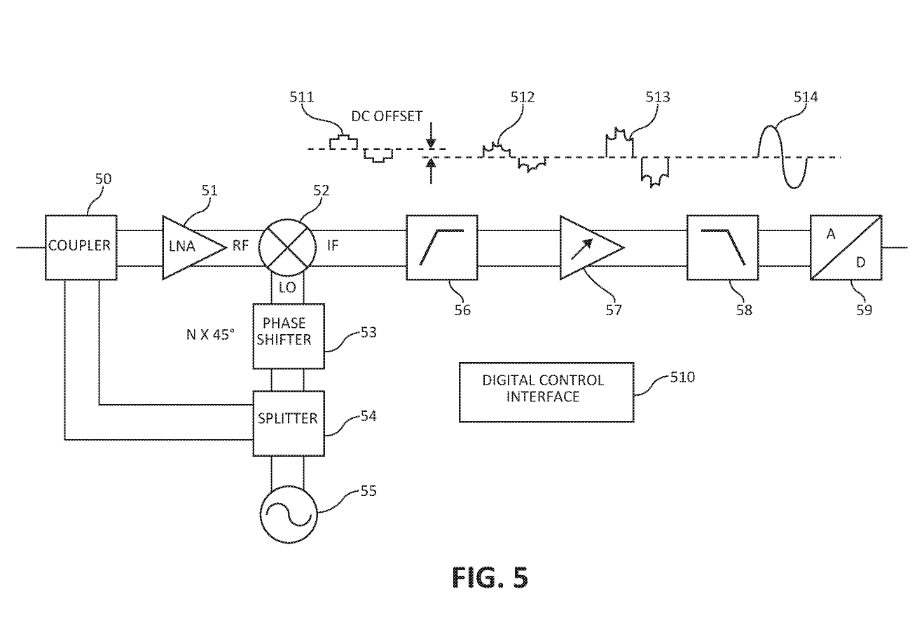

As already mentioned, in some embodiments it may be desirable to test a mixer together with circuitry coupled to the mixer. In some embodiments, components acting as high pass filters, for example serial capacitors, may be coupled to the IF output of the mixer, which then blocks a DC signal. In some embodiments, the phase difference may be set to a new value with a comparatively high frequency (for example 41 to 43 may be performed repetitively using a comparatively high frequency such as every 0.125 microseconds which corresponds to a speed of 8 MHz) such that a resulting signal at the IF output of the mixer may be, at least in part, transferred via such a high frequency path. In one embodiment, a periodic signal with a corresponding frequency of 8 MHz may be generated. An example for such an approach will now be explained with reference to FIG. 5.

FIG. 5 illustrates an embodiment of a device having a millimeter wave receiver path that includes a homodyne mixer 52. In normal operation for the device of FIG. 5, RF signals are received and fed via a coupler 50 and a low noise amplifier (LNA) 51 to an RF input of mixer 52. It should be noted that in the embodiment illustrated in FIG. 5, signals are represented as differential signals. In other embodiments, single-ended signals may be used.

An oscillator 55 generates a LO signal, which is fed via a splitter 54 and a phase shifter 53 to an LO input of mixer 52. It should be noted that in normal operation (outside of test mode), splitter 54 and phase shifter 53 are inactive and, for example, just pass through the signal generated by oscillator 55 to the LO input of mixer 52. An IF signal is output to an analog-to-digital converter 59 via a serial capacitance represented as a high pass filter 56, a variable gain amplifier 57 and a low pass filter 58. Low pass filter 58 may in particular serve as an anti-aliasing filter. Analog-to-digital converter 59 then outputs a digital representation of the received and down-converted signal.

In test mode, which may be controlled via digital control interface 510 (for example, a SPI), no RF signal is received externally. Instead, splitter 54 is operated to split the signal received from oscillator 55 and to feed a part of this signal, via coupler 50, to low noise amplifier 51 and therefore to the RF input of mixer 52. The other part of the signal is fed to the LO terminal of mixer 52 via phase shifter 53. Phase shifter 53 is now active to rapidly change the phase difference between the signals, as explained previously. For example, in one embodiment, digital control interface 510 may have a programming speed of 8 MHz and 45° phase steps are programmed every 0.125 μs. Generally, in various embodiments, the frequency of change of phase shifting is selected to be higher than a corner frequency of high pass filter 56.

This results in a DC offset of the signal output of the IF terminal of mixer 52 which has discrete values changing with a high frequency while 511 denotes an example signal. While high pass filter 56 removes DC components, as the signal 511 is periodic with a high frequency (e.g. 1 MHz in the example above, 8 MHz×45°/360°, an essentially differentiated version of the signal as schematically represented as 512 is output by high pass filter 56. This signal is amplified by amplifier 57, resulting in a signal waveform similar to the one schematically labelled with numeral 513. Low pass filter 58 then “smoothes” this signal. Depending on how exactly higher harmonic components are removed, a more or less sinusoidal waveform 514 results, which is then converted to a digital signal. This on the one hand may test the conversion range of analog-to-digital converter 59, and on the other hand tests the complete receive chain, and with an additional power measurement conversion gain may also be determined as explained above. Therefore, by changing the phase with a sufficiently high frequency, even in case of a high pass filter 56 a testing may be performed. In other embodiments, an additional output bypassing high pass filter 56 may be provided for testing purposes, which is then deactivated in normal operation.

In some embodiments, additionally the frequency of change of phase shifting may be varied to include at least one frequency below a nominal corner frequency of high pass filter 56. “Nominal” here refers to the corner frequency high pass filter 56 was designed for. In this way, an actual corner frequency of the high pass filter may be estimated e.g. by monitoring the signal strength passing high pass filter 56. Additionally or alternatively, the frequency of change of phase shift may be varied to include a frequency above a nominal corner frequency (also referred to as cutoff frequency) of low pass filter 58. By evaluating the attenuation of a signal at an output of low pass filter 58 compared to a signal where the frequency of change of phase shift is below the corner frequency of low pass filter 58, the actual corner frequency of low pass filter 58 may be estimated in some embodiments.

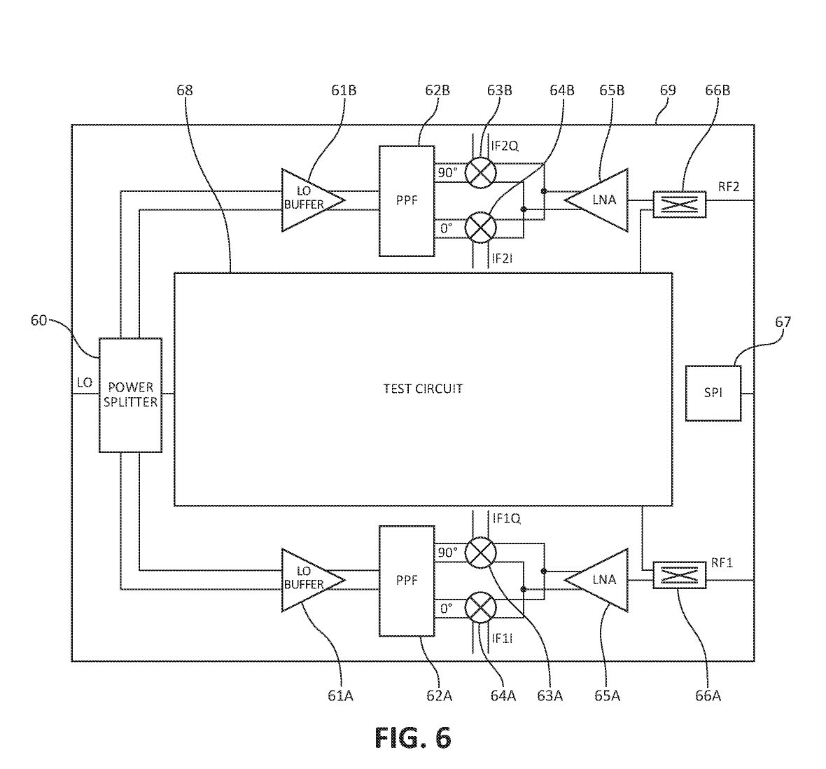

FIG. 6 shows a block diagram of a RF receiver device 69 according to an embodiment. Device 69 may be integrated on a signal chip in some embodiments, but in other embodiments may also be implemented using several chips.

Device 69 of FIG. 6 may for example be used as a receiver for a frequency modulated continuous wave (FMCW) radar system using a dual complex homodyne downconverter. An RF circuit portion of device 69 has two downconverters, a first downconverter comprising components 61A to 66A and a second downconverter comprising components 61B to 66B. Both downconverters receive a LO signal via a power splitter 60. In the embodiment of FIG. 6, the LO signal is depicted as differential signal using two lines. In other embodiments, single ended signals may be used.

First downconverter 61A to 66A receives a first radio frequency signal RF1, and second downconverter 61B to 66B receives a second radio frequency signal RF2. Components 61A to 66A of the first downconverter correspond to components 61B to 66B of the second downconverter, respectively (i.e. 61A corresponds to 61B, 62A corresponds to 62B etc.). Therefore, only components 61A to 66A will be described in detail and the description applies correspondingly to components 61B to 66B.

In the first downconverter, signal RF1 is fed to a low noise amplifier (LNA) 65A via a coupler 66A. LNA 65A outputs an amplified version of the radio frequency signal RF1 as a differential signal to respective RF inputs of a first mixer 63A and a second mixer 64A.

Furthermore, in the first downconverter, the LO signal is received from power splitter 60 at a LO buffer 61A. The LO signal is then fed to a polyphase filter 62A which outputs two versions of the LO signal with a phase offset of 90° relative to each other. In the example of FIG. 6, the LO signal with a 90° phase offset is fed to an LO input of first mixer 63A, and the LO signal with 0° phase shift is fed to second mixer 64A. First mixer 63A outputs a quadrature component IF1Q of the IF signal, and second mixer 64A outputs an in-phase component IF1I (in a similar manner, first mixer 63B outputs a quadrature component IF2Q, and second mixer 64B of the second downconverter outputs an in-phase component IF2I).

To test the mixers 63A, 64A, 63B and 64B, a test circuit 68 is provided. Test circuit 68 may operate as discussed previously with respect to FIGS. 1-5 by applying a phase-shifted version of the LO signal received from power splitter 60 to couplers 66A, 66B and therefore to the RF inputs of the mixer. Furthermore, test circuit 68 may comprise a power detector to determine a power of the signal coupled into coupler 66A, 66B. It should be noted that in some embodiments, the components illustrated in FIG. 2 (phase shifter, buffer, power detector) may be provided twice in test circuit 68, or one for each downconverter. In other embodiments, only one phase shifter, one buffer and one power detector may be included which controls phase shifting and testing for both downconverters. It should also be noted that the device 69 with a dual homodyne downconverter serves merely as an example where the testing discussed herein may be applied and such testing may be generally applied to devices containing mixers, in particular to RF devices including mixers for down conversion.

In view of the variations, modifications and alternatives discusses above, it is evident that the embodiments serve merely as examples, and are not to be construed as limiting.

What is claimed is:

1. A radio frequency (RF) device, comprising:
a mixer, wherein the mixer includes a RF input, a local oscillator (LO) input and an output; and
a test circuit that includes a phase shifter, wherein the test circuit is configured to apply, in a test mode, a first input signal to the LO input and a second input signal to the RF input, wherein the first input signal and the second input signal have essentially a same frequency, and wherein the phase shifter is configured to phase-shift the first input signal relative to the second input signal.

2. The device of claim 1, wherein the test circuit is configured to phase shift one or both of the first input signal and the second input signal.

3. The device of claim 1, further comprising:
a LO terminal coupled to the LO input; and
a RF terminal coupled to the RF input,
wherein the test circuit comprises a switch device configured to couple the LO terminal to the RF terminal during the test mode.

4. The device of claim 3, wherein the switch device comprises a buffer.

5. The device of claim 3, wherein the phase shifter is coupled between the switch device and the LO terminal.

6. The device of claim 3, wherein the phase shifter is coupled between the LO terminal and the LO input.

7. The device of claim 1, further comprising a local oscillator, wherein the first input signal and the second input signal are derived from an output of the local oscillator.

8. The device of claim 1, further comprising a digital control interface configured to control the phase shifter.

9. The device of claim 1, further comprising a power detector configured to measure a power of the second signal.

10. The device of claim 1, wherein the device is configured to vary the phase shift of the phase shifter and to determine a property of the mixer based on outputs of the mixer for different phase shifts.

11. The device of claim 1, further comprising a high pass filter component coupled to the output of the mixer, wherein the device is configured to vary the phase shifting with a frequency higher than a corner frequency of the high pass filter component.

12. The device of claim 11, further comprising a low pass filter component.

13. The device of claim 12, wherein the device is further configured to vary a frequency of the phase shifting from the frequency higher than the corner frequency of the high pass filter component to include at least one of a frequency below a nominal corner frequency of the high pass filter component or a frequency above a nominal corner frequency of the low pass filter component.

14. A method, comprising:
providing a first test signal and a second test signal, wherein the first test signal and the second test signal have essentially a same frequency;
setting one or more phase differences between the first test signal and the second test signal;
applying, for each one of the one or more phase differences, the first test signal to a local oscillator (LO) input of a mixer and the second test signal to a radio frequency (RF) input of the mixer;
measuring an output of the mixer for each one of the one or more phase differences to provide a corresponding one or more measurement results; and
evaluating the one or more measurement results to determine one or more values for the mixer.

15. The method of claim 14, wherein one of the one or more values is a peak-to-peak value.

16. The method of claim 14, wherein one of the one or more values is a conversion gain of the mixer.

17. The method of claim 14, further comprising filtering the output of the mixer to remove harmonic components from the one or more measurement results that are greater than a corner frequency and provide a high pass filtered output, and wherein the one or more measurement results are provided at a frequency that is greater than the corner frequency.

18. The method of claim 17, further comprising:
converting the high pass filtered output to a digital signal; and
evaluating one or both of a conversion range and a conversion gain of the digital signal.

19. A radio frequency (RF) device, comprising:
a local oscillator (LO) terminal;
a RF signal terminal;
a mixer that includes a LO input, a RF input and an intermediate frequency (IF) output, wherein the LO input is coupled to the LO terminal via a first coupler and the RF input is coupled to the RF terminal via a second coupler;
a buffer configured to couple the first coupler to the second coupler during a test mode;
a controllable phase shifter configured to phase-shift a LO input signal relative to a RF input signal during the test mode; and
a power detector configured to detect a power of the RF input signal.

20. The device of claim 19, wherein the mixer is a homodyne downconverter mixer.
